(19) United States
(12) Patent Application Publication
(10) Pub. No.: US 2009/0110887 A1
(43) Pub. Date: Apr. 30, 2009

(54) Lithographic Printing Plate Precursor

(75) Inventors: Takayuki Sanada, Sodegaura-shi (JP); Tomoya Terauchi, Nagoya-shi (JP); Akihiro Koide, Sodegaura-shi (JP)

Correspondence Address: FOLEY AND LARDNER LLP;SUITE 500, 3000 K STREET NW, WASHINGTON, DC, 20007, US

(73) Assignee: MITSUI CHEMICALS, INC., Minato-ku, Tokyo (JP)

(21) Appl. No.: 11/988,272

(22) PCT Filed: Jun. 14, 2006
(86) PCT No.: PCT/JP2006/311928

§ 371 Date: Apr. 4, 2008

(30) Foreign Application Priority Data
Jul. 8, 2005 (JP) 2005-199601

(51) Int. Cl. G03F 7/004; B32B 5/00

(52) U.S. Cl. 428/195.1; 430/270.1; 430/283.1

(57) ABSTRACT

An object of the present invention is to provide a lithographic printing plate precursor which is less apt to suffer from contamination by ablation in forming an image and having an excellent printing performance through image formation. A lithographic printing plate precursor comprises a base material (I), a photosensitive layer (II) containing a light/heat conversion agent on the base material (I), and a layer (III) covering the photosensitive layer (II), wherein the layer (III) covering the photosensitive layer contains both a water-soluble polymer and a hydrophobic polymer, and contains substantially no light/heat conversion agent is provided. The layer (III) covering the photosensitive layer is preferred to contain the water-soluble polymer and the hydrophobic polymer in a proportion of from 10:90 to 90:10 by mass.

### TECHNICAL FIELD

The present invention relates to a lithographic printing plate precursor. More particularly, it relates to a lithographic printing precursor in which a layer covering a photosensitive layer has a specific composition.

### BACKGROUND ART

When a lithographic printing plate precursor is irradiated by a particle wave or an electromagnetic wave, a property of an irradiated area of the plate precursor is changed by the particle wave and the electromagnetic wave or heat generated by conversion thereof, thereby forming an image. Thus it is known to be useful for printing plate.

Upon image formation (drawing) on the precursor, ablation occurs when the precursor is irradiated by particle wave or electromagnetic wave. However, an excessive occurrence of ablation may contaminate a light source used for exposure and working environment due to decomposition product scattered from the surface of the precursor. To prevent such a contamination due to the ablation, it is proposed to form a layer consisting of a water-soluble compound (hereinafter referred to as “an overcoat layer”) as a top layer of the printing plate precursor (refer to Patent document 1). It is also proposed to form a hydrophobic overcoat layer on a hydrophilic photosensitive layer, because such a water-soluble overcoat has a poor scratch resistance and causes contamination of dampening water (refer to Patent document 2). Further, it is reported that a hydrophilic overcoat layer being incorporated with a specific dye is prevented from ablation, and provides a printing image having an excellent visibility (refer to Patent document 3).

In addition, it is proposed to make an optical density of an overcoat layer less than that of a photosensitive layer (refer to Patent documents 4 and 5), or to incorporate both a water-soluble polymer and a hydrophobic polymer into an overcoat layer without addition of a hydrophilic binder into the photosensitive layer (refer to Patent document 5).

Such a lithographic printing plate precursor that has the overcoat layer proposed in these patent documents is apt to deteriorate printing performance, although there is an effect, to certain extent, of preventing scattering of decomposition product generated by ablation. There also have been made proposals for improving the printing performance by making such a complicated structure as described in Patent documents 3 and 5, but it is hard to say that a satisfactory level of the printing performance is achieved.

On the contrary, it is proposed a lithographic printing plate precursor that has a photosensitive layer containing a hydrophilic polymer, a hydrophobic polymer, a crosslinking agent and a light absorbent (refer to Patent document 6).

[Patent document 1] Japanese Patent Laid-Open Publication No. 2001-162963
[Patent document 2] Japanese Patent. Laid-Open Publication No. 2004-237605
[Patent document 3] Japanese Patent Laid-Open Publication No. 2004-148669.
[Patent document 4] Japanese Patent Application Laid-Open No. 2001-524894
[Patent document 5] Japanese Patent Laid-Open Publication No. 2003-63165
[Patent document 6] International Publication No. WO/01/83234 pamphlet

### DISCLOSURE OF THE INVENTION

### Problems to be Solved by the Invention

An object of the present invention is to provide a lithographic printing plate precursor which is less apt to suffer from contamination by decomposition products generated by ablation in the image formation and provides a printing plate having an excellent printing performance through the image formation.

### Means for Solving the Problems

The present inventors made such a surprising finding that covering a photosensitive layer of a lithographic printing plate precursor with a layer, which contains both a water-soluble polymer and a hydrophobic polymer at a specific ratio and no substantial amount of a light/heat conversion agent like a dye, is very effective for the compatibility between the prevention of contamination with decomposition products generated by ablation and the printing performance. And therefore the present invention is completed.

That is, the present invention is related to such a lithographic printing plate precursor as mentioned below.

[1] A lithographic printing plate precursor having a base material (I), a photosensitive layer (II) containing a light/heat conversion agent on the base material (I), and a layer (III) covering the photosensitive layer (II), wherein the layer (III) covering the photosensitive layer contains a water-soluble polymer and a hydrophobic polymer with no substantial amount of a light/heat conversion agent.

[2] The lithographic printing plate precursor, as described in [1], wherein the layer (III) covering the photosensitive layer contains a water-soluble polymer and a hydrophobic polymer in a proportion of from 10:90 to 90:10 by mass.

[3] The lithographic printing plate precursor, as described in [1] or [2], wherein the layer (III) covering the photosensitive layer contains a water-soluble polymer, and a hydrophobic polymer particulate that is dispersed in the water-soluble polymer.

[4] The lithographic printing plate precursor, as described in any of [1] to [3], wherein the hydrophobic polymer is a thermally-melting polymer particle.

[5] The lithographic printing plate precursor, as described in any of [1] to [4], wherein the water-soluble polymer is a polymer of a composition whose main component is one kind or two or more kinds of monomers selected from the group consisting of substituted or unsubstituted (meth)acrylamide and N-vinyl pyrrolidone.

[6] The lithographic printing plate precursor, as described in any of [1] to [5], wherein the photosensitive layer (II) further contains a water-soluble polymer and a hydrophobic polymer particulate.

[7] The lithographic printing plate precursor, as described in any of [1] to [6], wherein the photosensitive layer (II) is a hydrophilic resin layer formed from a composition containing a water-soluble polymer, a hydrophobic polymer particulate and a crosslinking agent.

[8] The lithographic printing plate precursor, as described in [6], wherein the hydrophilic polymer contained in the photosensitive layer (II) is a resin crosslinked with a crosslinking agent.

The present invention also relates to a printing plate as described below.

[9] The printing plate obtained by irradiating the lithographic printing plate precursor as described in any of [1] to [8].

### EFFECTS OF THE INVENTION

The lithographic printing plate precursor of the present invention is less apt to suffer from contamination by decomposition products generated by ablation in the image formation and it provides a printing plate which has an excellent printing performance through the image formation, so it has a great industrial value.

### BEST MODE FOR CARRYING OUT THE INVENTION

### 1. Lithographic Printing Plate Precursor of Present Invention

The lithographic printing plate precursor of the present invention has a base material (I), a photosensitive layer (II) formed on the base material (I), and a layer (III) covering the photosensitive layer (II). Of course, any other layer may be included so far as the effect of the present invention is not sacrificed.

[Base material (I)]

The base material (I) contained in the lithographic printing plate precursor of the present invention includes, but is not limited to, a plate-like or film-like base material. Examples of the material of the base material (I) include a metal such as aluminum, a plastic such as polypropylene, and paper or the like. A thickness of the base material (I) is, but not limited to, usually from 100 μm to 400 μm.

A surface treatment or the like may be applied to the base material (I), and the base material (I) may have an underlayer on its surface. By so doing, adhesion of the base material to a layer formed on the surface of the base material (I) (usually a photosensitive layer) can be improved. Preferable specific examples of such a surface treatment and underlayer are known in many literatures, and so they can be utilized. Examples of surface treatment include oxidation treatment, chromate treatment, sandblast treatment, corona discharge treatment and the like. Examples of the underlayer include a resin layer such as urethane.

### [Photosensitive Layer (II)]

The photosensitive layer (II) included in the lithographic printing plate precursor of the present invention is formed on the base material (I). A thickness of the photosensitive layer (II) is usually from 0.1 μm to 10 μm, and preferably, from 0.5 μm to 5 μm.

The property of the photosensitive layer (II) is changed by irradiation of light. Therefore, it is preferred that such a component that can change the property of a light-irradiated area in the photosensitive layer (II) either by a photoreaction or by heat generation (hereinafter also referred to as “light/heat conversion agent”) is contained in the photosensitive layer (II). Preferably, the photosensitive layer (II) contains a light/heat conversion agent.

The light/heat conversion agent may be a compound that can generate heat by absorbing light; for example, it means a compound that can generate heat by absorbing infrared ray (hereinafter, referred to as “infrared ray absorbent”). The light/heat conversion agent includes various kinds of pigment, dye, metal particulate and the like. Specific examples of the light/heat conversion agent include cyanine dye, phthalocyanine dye, naphthalocyanine dye, carbon black, metal oxide and the like. Preferable examples include cyanine dye, phthalocyanine dye, or naphthalocyanine dye.

The content of the light/heat conversion agent is preferably from 1 to 20 wt %, and more preferably, from 2 to 15 wt % relative to the total solid components consisting of the photosensitive layer (II).

As mentioned above, the property of the photosensitive layer (II) is changed by the irradiation of light, and it is preferred that the property is changed from the hydrophilic property to the lipophilic property (ink-adhesion). That is, it is preferred that the photosensitive layer (II) has the hydrophilic property, however, the hydrophilicity is changed to the lipophilicity property by light or heat upon irradiation of light. The photosensitive layer (II) that changes from hydrophilic to lipophilic by light or heat contains, for example, a hydrophilic polymer and a hydrophobic polymer particulate.

The hydrophilic polymer contained in the photosensitive layer (II) may also be a water-soluble polymer. The water solubility of such a water-soluble polymer is preferred to be 0.01 g/ml or more at 25° C. The water-soluble polymer is a polymer that has a hydrophilic group in the polymer chain and is not crystallized by a strong hydrogen bonding, and typically is a linear polymer having no crosslinkage. The water-soluble polymer may be any polymer that is soluble in water and a natural polymer such as gelatin and starch, a semi-synthetic polymer such as carboxymethyl cellulose, and a synthetic polymer such as polyvinyl alcohol can be exemplified. In particular, a synthetic polymer is preferable because of the degree of freedom of synthesis and molecular design.

Examples of the synthetic water-soluble polymer include a homopolymer or copolymer of a vinyl monomer having a hydrophilic group, besides polyvinyl alcohol. Examples of the homopolymer or copolymer of the vinyl monomer include the polymer from monomer composition containing a main component consisting of a monomer selected from the group consisting of substituted or unsubstituted (meth)acrylamide and N-vinyl pyrrolidone. The main component means 50 mol % or more component contained in the monomer composition. Further, examples of the synthetic water-soluble polymer include polyethylene glycol or the like. In particular, polyacrylamide, polyvinylpyrrolidone, and the like are preferred as the synthetic water-soluble polymer.

The molecular weight of the water-soluble polymer is preferably, but not limited to, approximately from one thousand to one million, and more preferably, approximately from ten thousands to five hundred thousands, so that the profile of the membrane is maintained after coating and drying. The water-soluble polymer can be used in one kind or two or more kinds.

The hydrophilic polymer contained in the photosensitive layer (II) which changes from hydrophilic to lipophilic by light or heat may be a resin having a crosslinkage (a crosslinked resin). Examples of such a crosslinked resin include a resin which is crosslinked the above described water-soluble polymer. The water-soluble polymer can be crosslinked with a crosslinking agent, and the agent is appropriately selected on the basis of a crosslinkable functional group contained in the polymer to be crosslinked. For example, if an amide group is contained in the water-soluble polymer to be crosslinked, the crosslinking agent may be an amino resin (for example melamine resin). The water solubility of the hydrophilic polymer is decreased by crosslinking, thereby water resistance of the photosensitive layer (II) can be increased.

It is preferred that the hydrophobic polymer particulate contained in the photosensitive layer (II), which changes from hydrophilic to lipophilic by light or heat, is melted by heat. The polymer that composes the hydrophobic polymer particulate may be any polymer that is not soluble in water. As most synthetic polymers are hydrophobic, it can be any polymer such as a polymer of vinyl monomer, polyester, polyurethane and the like. As described later, since the hydrophobic polymer can be used as a particulate, it is preferred that the hydrophobic polymer is a thermoplastic resin, and polyurethane, polyester or the like can be mentioned. The water solubility of the hydrophobic polymer is typically preferred to be 0 g/ml at 25° C., but the water solubility is acceptable to the extent that does not sacrifice the effect of the present invention.

The number-average molecular weight of the hydrophobic polymer is preferably, but not limited to, from ten thousands to one million, and particularly, from ten thousand to five hundred thousand. The hydrophobic polymer can be used in one-kind or two or more kinds.

The minimum membrane forming temperature of the hydrophobic polymer is preferred to be 50° C. or less, and more preferably, 30° C. or less. The minimum membrane forming temperature means the minimum temperature at which the adjacent particulate polymers are unified (melted) to form a film (membrane formation) when the dispersing solvent is evaporated. The hydrophobic polymer having the minimum membrane forming temperature 50° C. or less, is apt to melt in the photosensitive layer by laser irradiation for forming an image. The melt hydrophobic polymer is melted to each other, and the property of the photosensitive layer in an exposed area, can be changed from the hydrophilic property to the lipophilic property. The minimum membrane forming temperature can be measured according to the ISO2115 standard. As the test instrument, for example, the membrane forming temperature (MFT) measurement instrument, manufactured by IMOTO MACHINERY CO., LTD. can be used.

The hydrophobic polymer is preferred to be particulate, the average particle diameter of the hydrophobic polymer is preferably from 0.005 to 0.5 μm, and more preferably, from 0.01 to 0.3 μm. Here, the average particle diameter is a weight-average diameter that can be measured by dynamic light scattering or the like, for example, measured by Model LPA3100 manufactured by Otsuka Electronics Co., Ltd.

The weight ratio of the hydrophilic polymer to the hydrophobic polymer particulate contained in the photosensitive layer (II) is preferably from 15:85 to 70:30, and more preferably, from 25:75 to 70:30.

The photosensitive layer (II) of the lithographic printing plate precursor of the present invention may be a hydrophilic (ink repelling) resin layer which is formed from a composition containing a hydrophilic polymer (that can be a water-soluble polymer), a hydrophobic polymer particulate (preferably, a thermally-melting hydrophobic polymer particulate) and a light/heat conversion agent, and if necessary, a crosslinking agent. For example the hydrophilic resin layer can be formed, by coating and drying of an aqueous solution containing the composition on the base material (I) to form a membrane. Thus formed hydrophilic resin layer can have a phase-separated structure in which a hydrophilic polymer and a hydrophobic polymer are separated each other. In case that a crosslinking agent is contained, at least the hydrophilic polymer can be crosslinked with the crosslinking agent. Such a photosensitive layer is described, for example, in Patent document 6. Further, any other ingredient such as a surface active agent may be contained in the photosensitive layer (II).

### [Layer (III) Covering Photosensitive Layer]

Further, the layer (III) covering the photosensitive layer of the lithographic printing plate precursor of the present invention can prevent scattering of dust generated by ablation of the photosensitive layer when an image is formed by laser irradiation on the plate precursor. A thickness of the layer (III) covering the photosensitive layer is usually from 0.01 μm to 1 μm, and preferably, from 0.1 μm to 0.3 μm.

The layer (III) covering the photosensitive layer of the lithographic printing plate precursor of the present invention is characterized by containing a water-soluble polymer and a hydrophobic polymer and containing substantially no light/heat conversion agent.

The water-soluble polymer contained in the layer (III) covering the photosensitive layer is the same as explained as the hydrophilic polymer contained in the above-described photosensitive layer (II). Preferably, it is a polymer of monomer composition containing a main component consisting of monomer(s) selected from the group consisting of substituted or unsubstituted (meth)acrylamide and N-vinyl pyrrolidone. In particular, polyacrylamide, polyvinylpyrrolidone, and the like are preferable.

The hydrophobic polymer contained in the layer (III) covering the photosensitive layer may be any kind of polymer so far as it is insoluble in water, and can be the same as explained as the hydrophobic polymer contained in the above-described photosensitive layer (II). The hydrophobic polymer is preferred to be a thermoplastic polymer, and polyurethane, polyester, or the like can be mentioned as examples. The molecular weight of the hydrophobic polymer contained in the layer (III) covering the photosensitive layer is also in the same range as explained as the hydrophobic polymer contained in the photosensitive layer (II). The hydrophobic polymer can be used in one kind or two or more kinds.

The minimum membrane forming temperature of the hydrophobic polymer is preferred to be 50° C. or less, and more preferably, 30° C. or less. The minimum membrane forming temperature means the lowest temperature at which a film can be formed (membrane formation) by unifying (melting) the adjacent particulate polymers, when the dispersing solvent is evaporated. If the minimum membrane forming temperature is 50° C. or less, the hydrophobic polymer is easily melted by laser irradiation of the photosensitive layer for forming an image. The minimum membrane forming temperature can be measured according to the ISO2115 standard. As a test instrument, for example, the membrane forming temperature (MFT) measurement instrument, manufactured by IMOTO MACHINERY CO., LTD. can be used.

The hydrophobic polymer contained in the layer (III) covering the photosensitive layer is preferred to be particulate. That is, the layer (III) covering the photosensitive layer is preferred to be the layer containing a water-soluble polymer and a hydrophobic polymer particle dispersed in the water-soluble polymer. In addition, the hydrophobic polymer particulate is more preferably a thermally melting polymer particulate.

The average diameter of the hydrophobic polymer is preferably from 0.005 μm to 0.5 μm, and more preferably, from 0.01 μm to 0.3 μm. The layer (III) covering the photosensitive layer is required to be removed after forming an image, and it is necessary to prevent remaining of the hydrophobic polymer contained in the layer (III) covering the photosensitive layer in the non-imaged area (an unexposed area). Hence, it is preferable that the hydrophobic polymer particulate has such a particle diameter as described above.

The mass ratio of the water-soluble polymer to the hydrophobic polymer contained in the layer (III) covering the photosensitive layer is preferably from 10:90 to 90:10, and more preferably, from 10:90 to 60:40.

If the content ratio of the water-soluble polymer is too large, the water-soluble polymer is not entirely removed and apt to remain on an imaged area (an exposed area) of the photosensitive layer, even when the layer (III) covering the photosensitive layer is to be removed after forming an image by laser irradiation. Therefore, it becomes difficult to adhere ink on the imaged area when it is used as the printing plate.

On the contrary, if the content ratio of the hydrophobic polymer is too large, the hydrophobic polymer is not entirely removed and is apt to remain on a non-imaged area (an unexposed area) of the photosensitive layer, even when the layer (III) covering the photosensitive layer is to be removed after forming an image by laser irradiation. Therefore ink may be adhered on the non-imaged area (unexposed area) when it is used as the printing plate.

By constituting the layer (III) covering the photosensitive layer as such that the layer comprises a water-soluble polymer and a hydrophobic polymer, a lithographic printing plate precursor with a good sensitivity and with reduced paper consumption until a high quality of print is obtained can be produced.

As mentioned above, the layer (III) covering the photosensitive layer is characterized by not containing light/heat conversion agent. The light/heat conversion agent means a component which can generate heat by absorbing light, and further means a component which can generate heat by absorbing visible light or infrared ray. Examples of the light/heat conversion agent include various kinds of pigment, dye, metal particulate and the like.

Since the layer (III) covering the photosensitive layer does not contain the light/heat conversion agent, there is no problem of contamination of dampening water when the lithographic printing plate precursor of the present invention is used.

The layer (III) covering the photosensitive layer can be formed with a solution containing water, a water-soluble polymer and a dispersed hydrophobic polymer particulate. For example, the layer can be formed by coating and drying of this solution on the photosensitive layer to make a membrane.

### [Production of Lithographic Printing Plate Precursor]

The lithographic printing plate precursor of the present invention can be produced by any method, which may involve a step of membrane forming of the photosensitive layer (II) on the base material (I), and a step of membrane forming of the layer (III) covering the formed photosensitive layer (II).

A method of membrane forming of the photosensitive layer (II) on the base material (I) is appropriately selected in accordance with the photosensitive layer which is subjected to the membrane formation, and a known method can be adopted. For example, it can be formed by coating an aqueous solution containing a hydrophobic polymer particulate, a hydrophilic polymer, alight/heat conversion agent, and a crosslinking agent on the base material and then dried. During drying the aqueous solution, the hydrophobic polymer may be crosslinked with the crosslinking agent.

A method for forming a membrane of the layer (III) covering the photosensitive layer is also appropriately selected in accordance with layer which is subjected to the membrane formation, and a known method can be adopted. For example, it can be formed by coating an aqueous solution containing a hydrophobic polymer particulate and a water-soluble polymer on the photosensitive layer and then dried.

Concerning the method for forming a membrane of the photosensitive layer (II) and the layer (III) covering the photosensitive layer, and preferable embodiments thereof are known (for example, in the above-mentioned Patent documents 2 and 5), and these methods also can be applied to the present invention.

### 2. Lithographic Printing Plate of Present Invention

The printing plate of the present invention is produced by laser irradiation on the above-described lithographic printing plate precursor of the present invention. The lithographic printing plate of the present invention is preferred to be an offset printing plate using dampening water.

The wavelength of laser used for irradiation on the lithographic printing plate precursor of the present invention is appropriately selected in accordance with the light/heat conversion agent contained in the photosensitive layer (II), and it may be approximately from 750 nm to 1100 nm. The laser irradiation causes the property change of the exposed area, preferably from the hydrophilic property to the lipophilic property (ink-adhesion), and the lithographic printing plate with drawn image information can be obtained.

Since the photosensitive layer of the lithographic printing plate precursor of the present invention has the layer (III) covering the photosensitive layer, the ablation-induced decomposition of the photosensitive layer (II) is suppressed. In other words, the photosensitive layer containing a crosslinking agent and/or a light/heat conversion agent may generate dust by ablation upon laser irradiation, but scattering of the dust can be suppressed by the layer (III) covering the photosensitive layer.

Further, the photosensitive layer of the exposed area generates heat by exposure so that the hydrophobic polymer contained in the photosensitive layer (II) and the hydrophobic polymer contained in the layer (III) covering the photosensitive layer can be melted and strongly adhered to each other in the exposed area.

The exposed precursor, the printing plate, is set in a printing machine and used for printing according to a conventional method by using ink and dampening water. When a the precursor after the exposure is in contact with dampening water in the printing process, the hydrophilic polymer contained in the layer (III) covering the photosensitive layer is swollen so that the layer (III) covering the photosensitive layer is easily removed. At the same time, in the exposed area, as the hydrophobic polymer is adhered, the ink-adhesion is enhanced without remaining the water-soluble polymer in the exposed area. Indeed, in the unexposed area, because the layer covering the photosensitive layer (II) is removed by swelling the water-soluble polymer, thereby the hydrophilicity is enhanced in this area without remaining the hydrophobic polymer.

Because the layer (III) covering the photosensitive layer is easily removed, scumming appeared in trial print of a post-exposure printing process is immediately resolved. Further, there is no contamination of dampening water in the printing process, because the light/heat conversion agent is not contained in the layer (III) covering the photosensitive layer.

Hence, the lithographic printing plate of the present invention can have the following characteristics:

(1) Contamination caused by ablation in forming an image is minimized;
(2) Both ink-adhesion in the imaged area and hydrophilicity in the non-imaged area are excellent;
(3) No contamination of dampening water in the post-exposure printing process is observed; and
(4) Paper consumed until scumming disappears in trial printing is minimized.

### 1. EXAMPLE

The present invention is explained in more specifically by referring to the following examples, but the present invention is not limited to these examples.

### Examples 1-7, Comparative Examples 1-5

### Preparation of Base Material

An underlayer-coated aluminum plate (thickness of 0.24 mm) was prepared by coating, a urethane emulsion (Mitsui Chemicals, Inc., OLESTER™ UD350) with wire bar #10 on an aluminum plate, followed by drying at 150° C. for 1 minute.

### (Membrane Forming of Photosensitive Layer)

A photosensitive layer of 2 μm in thickness was formed by coating, an aqueous solution of a photosensitive resin composition shown in Table 1 (hereinafter, the unit is shown by parts by weight) with wire bar #14 on an underlayer-coated aluminum, followed by drying at 140° C. for 10 minutes.

TABLE 1

| | | |
|---|---|---|
| Polyacrylamide (Solid Content, 20 wt %) | 150 | Parts |
| (Mitsui Chemicals, Inc., Trade Mark: HOPELON 520B) | | |
| Methylated Methylolmelamine (Solid Content, 80 wt %) | 25 | Parts |
| (Mitsui Cytec, Ltd., Trade Mark: Cymel 385) | | |
| Urethane Emulsion (Solid Content, 40 wt %) | 125 | Parts |
| (Mitsui Chemicals, Inc., Trade Mark: OLESTER UD350) | | |
| Cyanine Dye Aqueous Solution (Solid Content, 5 wt %) | 260 | Parts |
| (Japan Photosensitive Dye Lab. Inc., IR-125) | | |
| Anionic Surface Active Agent (Solid Content, 70 wt %) | 0.14 | Parts |
| (DAI-ICHI KOGYO SEIYAKU CO., LTD., Trade Mark: | | |
| Neocol YSK) | | |

### (Membrane Forming of Layer Covering Photosensitive Layer)

A lithographic printing plate precursor having a layer (0.03 to 0.3 μm in thickness) covering a photosensitive layer was prepared by coating, a solution (0.3 to 3 wt % of a solid content) for a layer covering the photosensitive layer having compositions as shown in Table 2 with wire bar #10 on the above-described photosensitive layer, followed by drying at 110° C. for 1 minute.

In the solution for the layer covering the photosensitive layer in COMPARATIVE EXAMPLE 6, in addition to the water-soluble polymer and the hydrophobic polymer, a cyanine dye-based light/heat conversion agent (Japan Photosensitive Dye Lab. Inc., IR-125), which is a light/heat converting agent, was added (5 wt % in solid content). The weight ratio of water-soluble polymer:hydrophobic polymer:light/heat conversion agent=50:50:5 (weight % of solid content)

TABLE 2

| | | | | Membrane |
|---|---|---|---|---|
| | | | Wt Ratio | Thickness |
| | Water-Soluble Polymer | Hydrophobic Polymer | in Solid | (μm) |
| EXAMPLE 1 | Polyacrylamide | Urethane Emulsion | 50:50 | 0.1 |
| | (Mitsui Chemicals, | (Mitsui Chemicals, | | |
| | Inc., Trade | Inc., Trade | | |
| | Mark: HOPELON 520B) | Mark: OLESTER UD350) | | |
| EXAMPLE 2 | Polyvinylpyrrolidone | Urethane Emulsion | 50:50 | 0.1 |
| | (Wako Pure Chemical | (Mitsui Chemicals, | | |
| | Industries, Ltd., | Inc., Trade | | |
| | K-30) | Mark: OLESTER UD350) | | |
| EXAMPLE 3 | Polyvinylpyrrolidone | Urethane Emulsion | 50:50 | 0.05 |
| | (Wako Pure Chemical | (Mitsui Chemicals, | | |
| | Industries, Ltd., | Inc., Trade | | |
| | K-30) | Mark: OLESTER UD350) | | |
| EXAMPLE 4 | Polyvinylpyrrolidone | Urethane Emulsion | 50:50 | 0.3 |
| | (Wako Pure Chemical | (Mitsui Chemicals, | | |
| | Industries, Ltd., | Inc., Trade | | |
| | K-30) | Mark: OLESTER UD350) | | |
| EXAMPLE 5 | Polyvinylpyrrolidone | Urethane Emulsion | 10:90 | 0.2 |
| | (Wako Pure Chemical | (Mitsui Chemicals, | | |
| | Industries, Ltd., | Inc., Trade | | |
| | K-30) | Mark: OLESTER UD350) | | |
| EXAMPLE 6 | Polyvinylpyrrolidone | Polyester Emulsion | 33:67 | 0.2 |
| | (Wako Pure Chemical | (TOYOBO Co., Ltd., | | |
| | Industries, Ltd., | Trade Mark: Bironal | | |
| | K-30) | MD1200) | | |
| EXAMPLE 7 | Polyvinylpyrrolidone | Urethane Emulsion | 10:90 | 0.2 |
| | (Wako Pure Chemical | (DAI-ICHI KOGYO | | |
| | Industries, Ltd., | SEIYAKU CO., LTD., | | |
| | K-30) | Trade Mark: Super | | |
| COMPARATIVE | Without a layer covering a photosensitive layer | | | |
| EXAMPLE 1 | | | | |
| COMPARATIVE | Polyacrylamide | | 100:0 | 0.1 |
| EXAMPLE 2 | (Mitsui Chemicals, | | | |
| | Inc., H Trade | | | |
| COMPARATIVE | Polyvinylpyrrolidone | | 100:0 | 0.03 |
| EXAMPLE 3 | (Wako Pure Chemical | | | |
| | Industries, Ltd., | | | |
| COMPARATIVE | Polyvinylpyrrolidone | | 100:0 | 0.3 |
| EXAMPLE 4 | (Wako Pure Chemical | | | |
| | Industries, Ltd., | | | |
| COMPARATIVE | | Urethane Emulsion | 0:100 | 0.1 |
| EXAMPLE 5 | | (Mitsi Chemicals, | | |
| | | Inc., Trade | | |
| | | Mark: OLESTER UD350) | | |
| COMPARATIVE | Polyacrylamide | Urethane Emulsion | 50:50 | 0.1 |
| EXAMPLE 6 | (Mitsui Chemicals, | (Mitsi Chemicals, | | |
| | Inc. Trade | Inc., Trade | | |
| | Mark: HOPELON 520B) | Mark: OLESTER UD350) | | |

### Example 8, Comparative Examples 7-9

### Preparation of Base Material

The surface of an aluminum plate, JIS1050, 0.24 mm in thickness, was treated with a nylon brush (fiber diameter of 0.72 mm, fiber length of 80 mm) and a water suspension of Pamiston with an average particle diameter of 15 to 35 μm to make the surface rough, and then washed with ion-exchange water. Next, the surface-roughened aluminum plate was etched by immersing it in an aqueous solution of 10% sodium hydroxide at 70° C. for 30 seconds, and then washed with an aqueous solution of 10% nitric acid for neutralization. The obtained aluminum plate was treated by anodic oxidation in a 20% sulfuric acid aqueous solution at a current density of 30 A/dm² for 20 seconds, then further washed with water, and a surface-roughened anodically oxidized aluminum plate was prepared.

### (Membrane Forming of Photosensitive Layer)

A photosensitive layer of 2 μm in thickness was formed by coating, an aqueous solution of a photosensitive resin composition shown in Table 3 (hereinafter, parts shown by weight) with wire bare #10 on the above-described surface-roughened anodically oxidized aluminum plate, followed by drying at 110° C. for 1 minute.

TABLE 3

| | | |
|---|---|---|
| Polyacrylamide (Solid Content, 20 wt %) | 85 | Parts |
| (Mitsui Chemicals, Inc., Trade Mark: HOPELON 520B) | | |
| Urethane Emulsion (Solid Content, 40 wt %) | 137.5 | Parts |
| (Mitsui Chemicals, Inc., Trade Mark: OLESTER UD350) | | |
| Acryl Emulsion (Solid Content, 35 wt %) | 80 | Parts |
| (Mitsui Chemicals, Inc., Trade Mark: GLOSSDELL 204) | | |
| Cyanine Dye Aqueous Solution (Solid Content, 5 wt %) | 200 | Parts |
| (Japan Photosensitive Dye Lab. Inc., IR-125) | | |
| Trisodium Phosphate | 1.5 | Parts |
| (Wako Pure Chemical Industries, Ltd., Reagent | | |
| Grade, Solid) | | |
| Anionic Surface Active Agent (Solid Content, 100 wt %) | 0.5 | Parts |
| (DAI-ICHI KOGYO SEIYAKU CO., LTD., Trade Mark: | | |
| Prysurf A212E) | | |

### (Membrane Forming of Layer Covering Photosensitive Layer)

A lithographic printing plate precursor was prepared by coating, a solution (2 wt % of a solid content) having compositions as shown in Table 4 with wire bare #10 on the above mentioned photosensitive layer, and then drying at 110° C. for 1 minute to form a layer (0.2 μm in thickness) covering the photosensitive layer.

TABLE 4

| | | | | Membrane |
|---|---|---|---|---|
| | Water-Soluble | Hydrophobic | Wt Ratio | Thickness |
| | Polymer | Polymer | in Solid | (μm) |
| EXAMPLE 8 | Polyvinylpyrrolidone | | 10:90 | 0.2 |
| | (Wako Pure Chemical | | | |
| | Industries, Ltd., | | | |
| | K-30) | | | |
| COMPARATIVE | Polyacrylamide | | 100:0 | 0.2 |
| EXAMPLE 7 | (Mitsui Chemicals, | | | |
| | Inc., Trade Mark: | | | |
| | HOPELON 520B) | | | |
| COMPARATIVE | | Urethane Emulsion | 0:100 | 0.2 |
| EXAMPLE 8 | | (Mitsui Chemicals, | | |
| | | Inc., Trade Mark: | | |
| | | OLESTER UD350) | | |

| | |
|---|---|
| COMPARATIVE | Without a layer covering a photosensitive layer |
| EXAMPLE 9 | |

### (Drawing)

An information image with 175 line/inch was drawn on the plate precursor obtained respectively in the above-described examples and comparative examples by scanning irradiation with a semiconductor laser (wavelength of 830 nm), while collimating to adjust an energy density of 100 to 400 mJ/cm² on the printing precursor surface.

### (Printing Test)

Above mentioned printing plates were set in an offset printing machine (Sprint™ 26 produced by Komori Corporation). Using a 2% solution of H-Solution Astromark 3, produced by NIKKEN CHEMICALS CO., LTD., as dampening water, and Values-G™-M, produced by Dainippon Ink and Chemicals Incorporated, as ink.

One thousand papers were printed at 8000 rph of the printing speed. After pressing only a wet roller on a plate surface for 30 seconds at a low-speed revolution (4000 rph), feeding papers and the printing was started, which is in a manner that the ink roller is pressed on the plate surface simultaneously with the feeding of papers in an impression cylinder. The evaluation was made on the following 3 items (test results shown in Table 5);

(1) Trial print loss: a number of papers consumed until scumming disappears at trial printing.
(2) Sensitivity: a minimum level of exposure energy required for printing without irregularity.
(3) Degree of contamination by ablation.

### (Evaluation of Ablation)

A plain exposed part of the above mentioned drawn printing plate at a minimum level of exposure energy (sensitivity) required for ink-adhesion without irregularity was cut off to count the number of dust attached on the exposed surface generated by ablation using a scanning electron microscope, JSM-6380™, manufactured by JEOL. The dust counting was done for the area (view-field range; 166 μm×122 μm) of the highest dust density with a 5000-fold magnification.

TABLE 5

| | Trial Print | | Number of Dust |
|---|---|---|---|
| | Loss | Sensitivity | Particles |
| EXAMPLE 1 | 2 | 220 | 9 |
| EXAMPLE 2 | 5 | 170 | 12 |
| EXAMPLE 3 | 5 | 160 | 50 |
| EXAMPLE 4 | 0 | 210 | 0 |
| EXAMPLE 5 | 4 | 140 | 6 |
| EXAMPLE 6 | 0 | 190 | 5 |
| EXAMPLE 7 | 0 | 190 | 9 |
| EXAMPLE 8 | 10 | 260 | 10 |
| COMPARATIVE | 5 | 170 | 500 |
| EXAMPLE 1 | | | |
| COMPARATIVE | 0 | x *1 | 6 |
| EXAMPLE 2 | | | |
| COMPARATIVE | 0 | 220 | 500 |
| EXAMPLE 3 | | | |
| COMPARATIVE | 0 | x *1 | 2 |
| EXAMPLE 4 | | | |
| COMPARATIVE | 1000 or more | 100 | 7 |
| EXAMPLE 5 | | | |
| COMPARATIVE | 4 | 200 | 100 |
| EXAMPLE 6 | | | |
| COMPARATIVE | 0 | x *1 | 2 |
| EXAMPLE 7 | | | |
| COMPARATIVE | 1000 or more | 260 | 20 |
| EXAMPLE 8 | | | |
| COMPARATIVE | 10 | 260 | 500 |
| EXAMPLE 9 | | | |

A unit of sensitivity in Table 5 is “mJ/cm²”. A mark of “X*1” means that the ink was not adhered on a plate at an exposure energy of 400 mJ/cm².

### (Result)

As is clear from Table 5, dust generated by ablation upon laser irradiation were very few in EXAMPLES 1 to 8 (printing plates having a layer covering the photosensitive layer of the present invention) in comparison with those in COMPARATIVE EXAMPLES 1 and 9 (printing plates having no layer covering the photosensitive layer) or COMPARATIVE EXAMPLE 3 (a printing plate having a very thin layer covering a photosensitive layer), although there is no conspicuous deterioration in loss of papers at trial printing and sensitivity.

The printing plate obtained in COMPARATIVE EXAMPLES 2, 4, and 7, in which the layer covering the photosensitive layer contains a water-soluble polymer is inferior in sensitivity, whereas sensitivity of the printing plate of the present invention is very high. On the other hand, paper loss at the trial printing is large for the printing plates in COMPARATIVE EXAMPLE 5 or 8, wherein the layer covering the photosensitive layer contains a hydrophobic polymer, whereas paper loss at the trial printing is reduced for the printing plates according to the invention.

Furthermore, in the printing plates in which the layer covering the photosensitive layer contains a light/heat conversion agent IR-125 (COMPARATIVE EXAMPLE 6), the light/heat conversion agent dissolved into dampening water to cause contamination of the dampening water. In addition, a lot of dust particles were observed due to ablation of the layer covering the photosensitive layer.

In the printing plates of the present invention which has the photosensitive layer formed without using a crosslinking agent (EXAMPLE 8), the light/heat conversion agent dissolved into dampening water to make color of dampening water green.

### 2. INDUSTRIAL APPLICABILITY

A lithographic printing plate which is less apt to suffer contamination in the image formation and provides an excellent printing performance through image formation can be provided by using the printing plate precursor according to the invention.

The application claims the priority right of the Japanese Patent Application No. JP 2005/199601 filed on Jul. 8, 2005.

The entire disclosure of which is incorporated herein by reference.

1. A lithographic printing plate precursor comprising a base material (I), a photosensitive layer (II) containing a light/heat conversion agent on the base material (I), and a layer (III) covering the photosensitive layer (II), wherein the layer (III) covering the photosensitive layer contains a water-soluble polymer and a hydrophobic polymer, and comprising substantially no light/heat conversion agent.

2. The lithographic printing plate precursor according to claim 1, wherein the layer (III) covering the photosensitive layer contains a water-soluble polymer and a hydrophobic polymer in a proportion of from 10:90 to 90:10 by mass.

3. The lithographic printing plate precursor according to claim 1, wherein the layer (III) covering the photosensitive layer contains a water-soluble polymer, and a hydrophobic polymer particulate dispersed in the water-soluble polymer.

4. The lithographic printing plate precursor according to claim 1, wherein the hydrophobic polymer is a thermally-melting polymer particulate.

5. The lithographic printing plate precursor according to claim 1, wherein the water-soluble polymer is a polymer of a composition containing main component consisting of one kind or two or more kinds of monomers selected from the group consisting of substituted or unsubstituted (meth)acrylamide and N-vinyl pyrrolidone.

6. The lithographic printing plate precursor according to claim 1, wherein the photosensitive layer (II) further contains a water-soluble polymer and a hydrophobic polymer particulate.

7. The lithographic printing plate precursor according to claim 1, wherein the photosensitive layer (II) is a hydrophilic resin layer formed from a composition containing a water-soluble polymer, a hydrophobic polymer particulate, a crosslinking agent and a light/heat conversion agent.

8. The lithographic printing plate precursor according to claim 6, wherein the hydrophilic polymer contained in the photosensitive layer (II) is a hydrophilic polymer that is crosslinked with a crosslinking agent.

9. The lithographic printing plate that is obtained by irradiating the lithographic printing plate precursor according to claim 1.
